(19) United States
(12) Patent Application Publication
(10) Pub. No.: US 2026/0343790 A1
(43) Pub. Date: Oct. 29, 2026

(54) COOLING DEVICE AND PROJECTOR

(71) Applicant: SEIKO EPSON CORPORATION, Tokyo (JP)

(72) Inventor: Hiroshi TSUCHITANI, Shiojiri-shi (JP)

(21) Appl. No.: 19/655,769

(22) Filed: Apr. 23, 2026

(30) Foreign Application Priority Data
Apr. 24, 2025 (JP) 2025-072238

(51) Int. Cl. H05K 7/20; G03B 21/16

(52) U.S. Cl. CPC H05K 7/20145; G03B 21/16; H05K 7/20254; H05K 7/20263; H05K 7/20272; H05K 7/20409

(57) ABSTRACT

A cooling device according to the present disclosure includes: a liquid cooling unit including a heat exchanger configured to absorb heat generated by a heat source with a liquid refrigerant, a pump configured to cause the liquid refrigerant to flow, a tank configured to store the liquid refrigerant, and a heat dissipation member configured to dissipate heat of the liquid refrigerant; and a fan configured to cause cooling air to flow to the heat dissipation member of the liquid cooling unit, wherein the cooling air flows through a space surrounded by at least some of components of the liquid cooling unit.

The present application is based on, and claims priority from JP Application Serial Number 2025-072238, filed Apr. 24, 2025, the disclosure of which is hereby incorporated by reference herein in its entirety.

### BACKGROUND

### 1. Technical Field

The present disclosure relates to a cooling device and a projector.

### 2. Related Art

In a projector disclosed in JP-A-2023-032764, heat generated in a light source unit is transferred to a refrigerant in a heat exchanger, the refrigerant is circulated to a radiator located at a position at a distance from the light source unit via a pipe, and the heat is released by exhausting air from fans adjacent to the radiator.

JP-A-2023-032764 is an example of the related art.

In the projector described above, when a tank, a pump, or the like constituting a cooling device is randomly disposed in a flow path of cooling air to the radiator in order to reduce the size of the device configuration, a flow space for the cooling air cannot sufficiently be ensured, and the flow of the cooling air is hindered to thereby incur a decrease in cooling efficiency. Then, when a dedicated duct is provided in order to efficiently guide the cooling air to the radiator, the device configuration grows in size.

### SUMMARY

In order to solve the problem described above, according to an aspect of the present disclosure, there is provided a cooling device including: a liquid cooling unit including a heat exchanger configured to absorb heat generated by a heat source with a liquid refrigerant, a pump configured to cause the liquid refrigerant to flow, a tank configured to store the liquid refrigerant, and a heat dissipation member configured to dissipate heat of the liquid refrigerant; and a fan configured to cause cooling air to flow to the heat dissipation member of the liquid cooling unit, wherein the cooling air flows through a space surrounded by at least some of components of the liquid cooling unit.

According to an aspect of the present disclosure, there is provided a projector including the cooling device according to the aspect of the present disclosure and the heat source.

### BRIEF DESCRIPTION OF THE DRAWINGS

FIG. 1 is a diagram showing a configuration of a projector according to a first embodiment.

FIG. 2 is a schematic configuration diagram of a light source unit.

FIG. 3 is a perspective view showing a configuration of a cooling device.

FIG. 4 is a perspective view showing a configuration of a cooling device according to a second embodiment.

FIG. 5 is a perspective view showing a configuration of a cooling device according to a third embodiment.

FIG. 6 is an exploded perspective view showing a configuration of a principal part of a liquid cooling unit in the third embodiment.

### DESCRIPTION OF EMBODIMENTS

An embodiment of the present disclosure will hereinafter be described with reference to the drawings.

Note that in the drawings described below, elements may be illustrated at different dimensional scales in accordance with the elements in some cases in order to make the elements eye-friendly.

### First Embodiment

The projector according to the present embodiment modulates illumination light emitted from the light source unit to generate image light according to image information, and projects the image light thus formed on a target projection surface such as a screen in an enlarged manner.

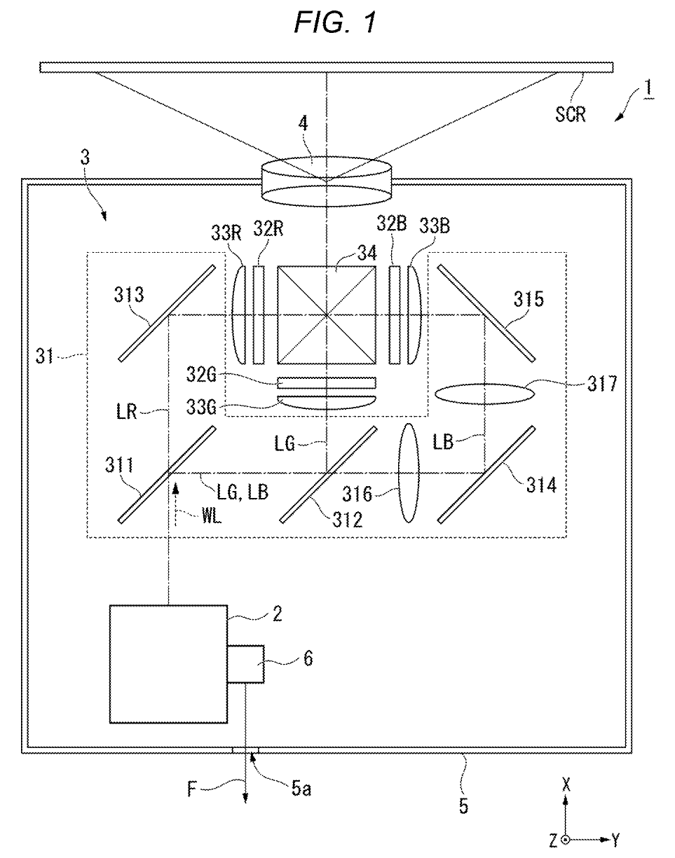

FIG. 1 shows a configuration of a projector of the present embodiment.

As shown in FIG. 1, the projector 1 according to the present embodiment includes a light source unit 2, an image forming unit 3, a projection optical unit 4, an exterior housing 5, and a cooling device 6.

In the following description, an X-Y-Z orthogonal coordinate system is used as necessary.

In each of the drawings, the Y axis is an axis along a direction in which the projection optical unit 4 projects image light, that is, an axis along an optical axis of the projection optical unit 4. The X axis is an axis that is orthogonal to the Y axis and extends along a left-right direction of a screen SCR as a projection surface. The Z axis is an axis that is orthogonal to the X axis and the Y axis, and extends along an up-down direction of the screen SCR.

In the description of the present embodiment, a direction along the Z axis is referred to as an "up-down direction Z", +Z is referred to as an "upper side", -Z is referred to as a "lower side", a direction along the X axis is referred to as a "left-right direction X", +X is referred to as a "right side", -X is referred to as a "left side", a direction along the Y axis is referred to as a "front-rear direction Y", +Y is referred to as a "front side", and -Y is referred to as a "rear side".

Note that the up-down direction Z, the left-right direction X, and the front-rear direction Y are merely names for describing the arrangement relationship of the components of the projector 1, but do not define the actual installation posture and direction in the projector 1.

The light source unit 2 supplies illumination light WL as white light to the image forming unit 3. Details of a configuration of the light source unit 2 will be described later.

The image forming unit 3 includes a color separation optical system 31, a light modulation device 32R, a light modulation device 32G, a light modulation device 32B, and a combining optical system 34.

The color separation optical system 31 separates the illumination light WL from the light source unit 2 into red light LR, green light LG, and blue light LB, and guides the red light LR, the green light LG, and the blue light LB to the respective light modulation devices 32R, 32G, and 32B. The color separation optical system 31 includes a first dichroic mirror 311, a second dichroic mirror 312, a first reflecting mirror 313, a second reflecting mirror 314, a third reflecting mirror 315, a first relay lens 316, and a second relay lens 317.

The first dichroic mirror 311 transmits the red light LR and reflects the green light LG and the blue light LB. The second dichroic mirror 312 reflects the green light LG and transmits the blue light LB out of the green light LG and the blue light LB reflected by the first dichroic mirror 311. The first reflecting mirror 313 reflects the red light LR. The second reflecting mirror 314 and the third reflecting mirror 315 reflect the blue light LB. The first relay lens 316 is disposed between the second dichroic mirror 312 and the second reflecting mirror 314, and the second relay lens 317 is disposed between the second reflecting mirror 314 and the third reflecting mirror 315. Each of the first relay lens 316 and the second relay lens 317 is disposed on an optical path of the blue light BL to suppress a loss of the blue light BL.

The light modulation device 32R is configured with a liquid crystal panel that modulates the red light LR in accordance with image information to form an image. The light modulation device 32G is configured with a liquid crystal panel that modulates the green light LG in accordance with image information to form an image. The light modulation device 32B is configured with a liquid crystal panel that modulates the blue light BL in accordance with image information to form an image.

Field lenses 33R, 33G, and 33B are disposed at the light incident side of the light modulation devices 32R, 32G, and 32B, respectively. Note that although not shown in the drawings, incident-side polarization plates are disposed between the light modulation devices 32R, 32G, and 32B and the field lenses 33R, 33G, and 33B, respectively, and exit-side polarization plates are disposed between the combining optical system 34 and the light modulation devices 32R, 32G, and 32B, respectively.

The combining optical system 34 combines image light output from the light modulation device 32R, image light output from the light modulation device 32G, and image light output from the light modulation device 32B with each other. The combining optical system 34 is configured with a cross dichroic prism obtained by bonding four right angle prisms to each other to form a substantially square planar shape. In the cross dichroic prism, dielectric multilayer films are disposed on the interfaces having a substantially X shape formed by bonding the right angle prisms to each other.

The image light output from the combining optical system 34 is projected in an enlarged manner onto the screen SCR by the projection optical unit 4. The projection optical unit 4 includes a plurality of lenses.

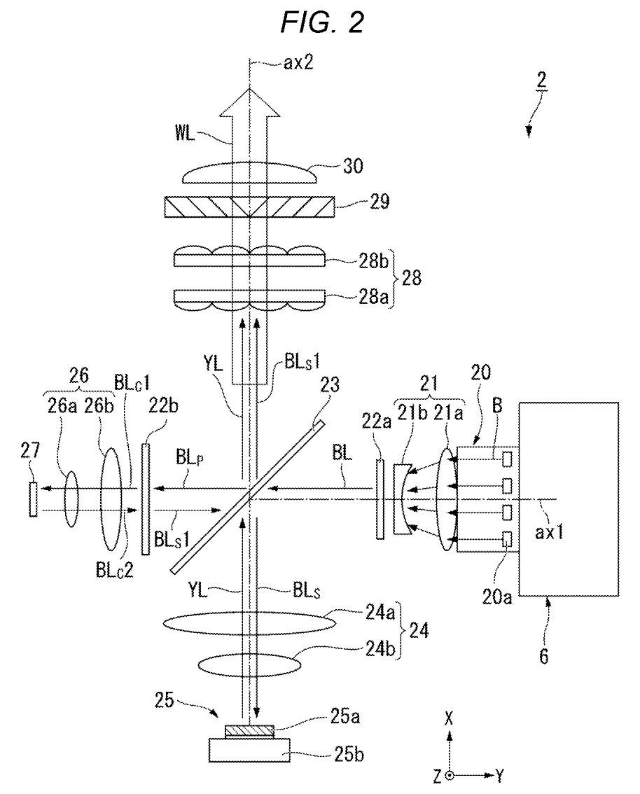

FIG. 2 is a schematic configuration diagram of the light source unit 2.

As shown in FIG. 2, the light source unit 2 is provided with a light source 20, an afocal optical system 21, a first wave plate 22a, a polarization split element 23, a first light collection optical system 24, a wavelength conversion element 25, a second wave plate 22b, a second light collection optical system 26, a diffuse reflection element 27, an integrator optical system 28, a polarization conversion element 29, and a superimposing lens 30.

In FIG. 2, the central axis of the blue light BL emitted from the light source 20 is defined as a first optical axis ax1. The central axis of the illumination light WL emitted from the light source unit 2 is defined as a second optical axis ax2.

The light source 20, the afocal optical system 21, the first wave plate 22a, the polarization split element 23, the second wave plate 22b, the second light collection optical system 26, and the diffuse reflection element 27 are sequentially arranged on the first optical axis ax1. The wavelength conversion element 25, the first light collection optical system 24, the polarization split element 23, the integrator optical system 28, the polarization conversion element 29, and the superimposing lens 30 are sequentially arranged on the second optical axis ax2. The first optical axis ax1 and the second optical axis ax2 are present in the same plane and are orthogonal to each other.

The light source 20 includes a plurality of light emitting elements 20a. The plurality of light emitting elements 20a are arranged in an array in a plane orthogonal to the second optical axis ax2. The light emitting elements 20a are each formed of a semiconductor laser and emit a blue light beam B in a first wavelength band corresponding to a blue wavelength band of, for example, 445 nm to 465 nm. As described above, the light source 20 outputs the blue light BL formed of a plurality of blue light beams B. That is, the light emitting element 20a outputs the blue light BL to be incident on the wavelength conversion element 25.

The blue light BL emitted from the light source 20 enters the afocal optical system 21. The afocal optical system 21 adjusts a luminous flux diameter of the blue light BL. In the case of the present embodiment, the afocal optical system 21 reduces the luminous flux diameter of the blue light BL. The afocal optical system 21 is configured with a convex lens 21a and a concave lens 21b.

The blue light BL having been transmitted through the afocal optical system 21 enters the first wave plate 22a. The first wave plate 22a is formed of, for example, a half-wave plate which is made rotatable. The blue light BL output from the light source 20 is linearly polarized light having a predetermined polarization direction. By appropriately setting a rotation angle of the first wave plate 22a, it is possible to convert the blue light BL transmitted through the first wave plate 22a into light including an S-polarized light component and a P-polarized light component with respect to the polarization split element 23 in the subsequent stage at a predetermined ratio. Further, the ratio between the S-polarized light component and the P-polarized light component can be changed by changing the rotation angle of the first wave plate 22a.

The blue light BL including the S-polarized component and the P-polarized component generated by passing through the first wave plate 22a enters the polarization split element 23. The polarization split element 23 is formed of, for example, a polarization beam splitter having wavelength selectivity. The polarization split element 23 is disposed so as to form an angle of 45° with respect to each of the first optical axis ax1 and the second optical axis ax2.

The polarization split element 23 has a polarization split function of separating the blue light BL into blue light BLs as an S-polarized component and blue light BLp as a P-polarized component with respect to the polarization split element 23. Specifically, the polarization split element 23 reflects the blue light BLs as the S-polarized component and transmits the blue light BLp as the P-polarized component. Further, the polarization split element 23 has a color separation function of transmitting fluorescence YL different in wavelength band from the blue light BL regardless of the polarization state.

The blue light BLs as the S-polarized light output from the polarization split element 23 enters the first light collection optical system 24. The first light collection optical system 24 collects the blue light BLs toward the wavelength conversion element 25. The first light collection optical system 24 is configured with a convex lens 24a and a convex lens 24b. The number of lenses constituting the first light collection optical system 24 is not particularly limited. The blue light BLs having been emitted from the first light collection optical system 24 enters the wavelength conversion element 25 in a converged state.

The wavelength conversion element 25 includes a wavelength conversion member 25a and a substrate 25b. The wavelength conversion member 25a includes phosphor particles, and is excited by the blue light BLs to emit the fluorescence YL in a second wavelength band different from the first wavelength band of the blue light BL. A material of the phosphor particles includes, for example, an yttrium-aluminum-garnet-based (YAG-based) phosphor.

The second wavelength band to which the fluorescence YL belongs is a yellow wavelength band in a range of, for example, 490 to 750 nm. The substrate 25b supports the wavelength conversion member 25a and functions as a heat dissipation member that dissipates heat of the wavelength conversion member 25a. Based on such a configuration, the wavelength conversion element 25 is arranged to generate and emit the fluorescence YL by being excited by the blue light BLs.

The fluorescence YL having been emitted from the wavelength conversion element 25 is collimated by the first light collection optical system 24 and then enters the polarization split element 23. The fluorescence YL is transmitted through the polarization split element 23.

Meanwhile, the blue light BLp as the P-polarized light output from the polarization split element 23 enters the second wave plate 22b. The second wave plate 22b is disposed in the optical path between the polarization split element 23 and the diffuse reflection element 27. The second wave plate 22b is formed of a quarter-wave plate. Therefore, the blue light BLp as the P-polarized light output from the polarization split element 23 is converted by the second wave plate 22b into, for example, blue light BLc1 as clockwise circularly polarized light, and then enters the second light collection optical system 26.

The second light collection optical system 26 is configured with a convex lens 26a and a convex lens 26b. The number of lenses constituting the second light collection optical system 26 is not particularly limited. The second light collection optical system 26 causes the blue light BLc1 to be incident on the diffuse reflection element 27 in a converged state.

The diffuse reflection element 27 is disposed at an opposite side of the light source 20 with respect to the polarization split element 23. The diffuse reflection element 27 diffusely reflects, toward the polarization split element 23, the blue light BLc1 emitted from the second light collection optical system 26. As the diffuse reflection element 27, it is preferable to use what does not disturb the polarization state while performing the Lambertian reflection on the blue light BLc1.

The light diffusively reflected by the diffuse reflection element 27 is hereinafter referred to as blue light BLc2. According to the present embodiment, the blue light BLc2 having a substantially uniform illuminance distribution is obtained by diffusely reflecting the blue light BLc1. The blue light BLc1 as right-handed circularly polarized light becomes the blue light BLc2 as left-handed circularly polarized light due to the reflection.

The blue light BLc2 is converted by the second light collection optical system 26 into collimated light and then reenters the second wave plate 22b. On this occasion, the blue light BLc2 as the left-handed circularly polarized light is converted into the blue light BLs1 as the S-polarized light by passing through the second wave plate 22b. The blue light BLs1 as the S-polarized light is reflected by the polarization split element 23 toward the integrator optical system 28.

Thus, the blue light BLs1 is used as the illumination light WL along with the fluorescence YL having been transmitted through the polarization split element 23. That is, the blue light BLs1 and the fluorescence YL are emitted toward the same direction from the polarization split element 23, and the illumination light WL as the white light obtained by combining the blue light BLs1 and the yellow fluorescence YL with each other is generated.

The illumination light WL is output toward the integrator optical system 28. The integrator optical system 28 is formed of a first lens array 28a and a second lens array 28b. Each of the first lens array 28a and the second lens array 28b has a configuration in which a plurality of microlenses is arranged in an array.

The illumination light WL having been transmitted through the integrator optical system 28 enters the polarization conversion element 29.

The polarization conversion element 29 is configured with a polarization split film and a wave plate. The polarization conversion element 29 converts the illumination light WL containing the fluorescence YL as non-polarized light into linearly polarized light.

The illumination light WL having been transmitted through the polarization conversion element 29 enters the superimposing lens 30. The superimposing lens 30 homogenizes the illuminance distribution of the illumination light WL in an illumination target region in cooperation with the integrator optical system 28. In this manner, the light source unit 2 generates the illumination light WL.

The exterior housing 5 incorporates the light source unit 2, the image forming unit 3, and the cooling device 6, and constitutes an exterior of the projector 1.

The projector 1 according to the present embodiment includes a heat source disposed in the exterior housing 5. Specifically, a heat source of the projector 1 is the light source unit 2.

The projector 1 according to the present embodiment includes the cooling device 6 for cooling the heat generated by the light source unit 2 as the heat source.

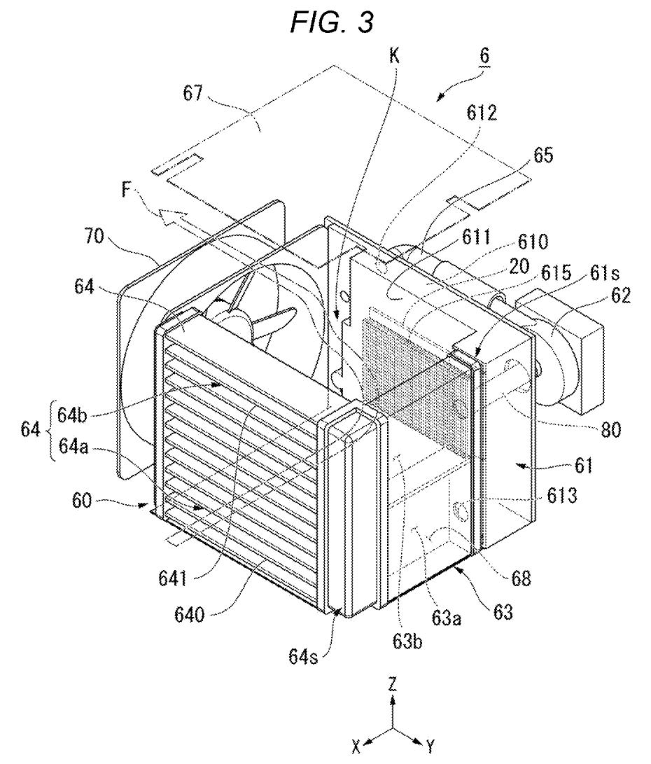

FIG. 3 is a perspective view illustrating a configuration of the cooling device 6.

As shown in FIG. 3, the cooling device 6 includes a liquid cooling unit 60 and a fan 70. The liquid cooling unit 60 includes a heat exchanger 61, a pump 62, a tank 63, and a heat dissipation member 64 as components.

The heat exchanger 61 absorbs the heat generated in the light source unit (the heat source) 2 with a liquid refrigerant. The liquid refrigerant is a heat exchanging liquid circulating inside the heat exchanger 61. The heat exchanger 61 is a plate-shaped member that includes cooling flow paths which are formed between a plurality of fins 615 disposed inside, and through which the liquid refrigerant can circulate, and cools the light source unit 2 by transferring, to the liquid refrigerant, the heat having been transferred to the plurality of fins 615. The heat exchanger 61 has a heat exchange surface 610 that supports the light source unit 2 and a back surface 611 opposite to the heat exchange surface 610.

The pump 62 causes the liquid refrigerant to flow. Specifically, the pump 62 supplies the liquid refrigerant low in temperature cooled by the heat dissipation member 64 as described later to the heat exchanger 61 via a piping member 65. The pump 62 of the present embodiment is, for example, a centrifugal pump.

The heat exchanger 61 further includes an inflow portion 612 into which the liquid refrigerant flows from the pump 62 via the piping member 65, and an outflow portion 613 from which the liquid refrigerant flows out toward the tank 63 side. The inflow portion 612 is disposed in a region located at the -Y side and the +Z side with respect to the light source unit 2 out of the heat exchange surface 610 of the heat exchanger 61. The liquid refrigerant flows into the inflow portion 612 from the outside. The inflow portion 612 communicates with an internal space, and the liquid refrigerant flowing into the inflow portion 612 flows into spaces between the plurality of fins 615 forming the cooling flow paths disposed inside. The plurality of fins 615 is disposed at least in a region overlapping, in plan view, the light source 20 as a cooling target. The outflow portion 613 is disposed in a region located at the +Y side and the -Z side with respect to the light source unit 2 out of the back surface 611 of the heat exchanger 61. The outflow portion 613 communicates with the internal space, and causes the liquid refrigerant having flowed through the cooling flow path to flow to the outside.

The tank 63 stores the liquid refrigerant. The tank 63 mainly functions as, for example, a buffer that stores a supplementary refrigerant for supplementing a decrease in the liquid refrigerant due to volatilization in a refrigerant flow path. The tank 63 in the present embodiment is made of metal and is formed integrally with the heat dissipation member 64. The tank 63 may be configured separately from the heat dissipation member 64.

The tank 63 includes a first storage portion 63a and a second storage portion 63b. The first storage portion 63a and the second storage portion 63b are arranged side by side in order from the -Z side toward the +Z side in the up-down direction Z. Since the first storage portion 63a and the second storage portion 63b are partitioned from each other, the liquid refrigerant in the first storage portion 63a and the liquid refrigerant in the second storage portion 63b do not mix with each other.

The first storage portion 63a is coupled to the outflow portion 613 of the heat exchanger 61, and the liquid refrigerant from the heat exchanger 61 flows into the first storage portion 63a. The liquid refrigerant flows into the first storage portion 63a from the heat exchanger 61 and is supplied to the heat dissipation member 64. The liquid refrigerant the heat of which has been dissipated by the heat dissipation member 64 flows into the second storage portion 63b, and the second storage portion 63b causes the liquid refrigerant to flow to the pump 62 via a piping member 80 described later.

The heat dissipation member 64 is configured with a radiator that dissipates heat from the liquid refrigerant. The heat dissipation member 64 causes the liquid refrigerant to flow into or out of the heat exchanger 61 via the tank 63. The heat dissipation member 64 includes a first heat dissipation portion 64a and a second heat dissipation portion 64b.

The first heat dissipation portion 64a includes a plurality of first heat dissipation members 640 each having a plate shape extending in the front-rear direction Y and arranged side by side in the up-down direction Z. The first heat dissipation portion 64a causes the liquid refrigerant having inflowed from the first storage portion 63a of the tank 63 to flow from the +Y side toward the -Y side through the cooling flow path in each of the first heat dissipation members 640 to thereby exchange heat between cooling air F passing through the first heat dissipation portion 64a and the liquid refrigerant. Thus, the first heat dissipation portion 64a decreases the temperature of the liquid refrigerant flowing through the plurality of first heat dissipation members 640.

The liquid refrigerant cooled by the first heat dissipation portion 64a flows into the second heat dissipation portion 64b. Similarly to the first heat dissipation portion 64a, the second heat dissipation portion 64b includes a plurality of second heat dissipation members 641 each having a plate shape extending in the front-rear direction Y and arranged side by side in the up-down direction Z. The second heat dissipation portion 64b causes the liquid refrigerant having inflowed from the first heat dissipation portion 64a to flow from the -Y side toward the +Y side in the cooling flow path formed in each of the second heat dissipation members 641 to thereby exchange the heat between the cooling air F passing through the second heat dissipation portion 64b and the liquid refrigerant. Thus, the second heat dissipation portion 64b releases the heat of the liquid refrigerant flowing through each of the second heat dissipation members 641.

The liquid refrigerant the heat of which has been dissipated by the second heat dissipation portion 64b flows into the second storage portion 63b of the tank 63. The second storage portion 63b discharges the liquid refrigerant to the pump 62 via the piping member 80. The piping member 80 is disposed below the liquid surface of the liquid refrigerant stored in the second storage portion 63b in the vertical direction (lower side -Z in the up-down direction Z). According to this configuration, since it is difficult for air bubbles to enter the liquid refrigerant sent to the pump 62 via the piping member 80, it is possible to suppress an occurrence of an operation failure due to air entrainment of the pump 62.

The piping member 80 is directly coupled to the pump 62 in a state of penetrating the heat exchanger 61 without communicating with the cooling flow path in the heat exchanger 61. Therefore, the liquid refrigerant flowing in the piping member 80 is supplied to the pump 62 without mixing with the liquid refrigerant flowing in the heat exchanger 61.

The fan 70 is an exhaust fan that causes the cooling air F to flow to the heat dissipation member 64 of the liquid cooling unit 60. Although the fan 70 in the present embodiment is an axial fan, the type of the fan is not limited thereto, and a centrifugal fan or a sirocco fan may be used.

In the cooling device 6 in the present embodiment, the components are arranged so that the cooling air F from the fan 70 flows through a space K having a substantially cubic shape. The space K through which the cooling air from the fan 70 flows is configured by being defined by at least some of the components of the liquid cooling unit 60.

Specifically, the heat exchanger 61 is disposed along the Y-Z plane (a first plane). The heat dissipation member 64 is disposed along the Y-Z plane so as to face the heat exchanger 61. That is, the heat exchanger 61 and the heat dissipation member 64 each having a plate shape are arranged in such an orientation that the thickness direction thereof coincides with the X direction. Therefore, the heat exchanger 61 covers the space K from the left side (-X) in the left-right direction X, and the heat dissipation member 64 covers the space K from the right side (+X) in the left-right direction X.

The tank 63 is disposed along an X-Z plane (a second plane) crossing the Y-Z plane. That is, the tank 63 having a plate shape is disposed in an orientation in which the thickness direction coincides with the Y direction. The tank 63 is coupled to one end side 61s located at the front side (+Y) of the heat exchanger 61 and one end side 64s located at the front side (+Y) of the heat dissipation member 64. Therefore, the tank 63 covers the space K from the front side (+Y) in the front-rear direction Y. In the case of the present embodiment, the tank 63 is coupled to the one end side 61s of the heat exchanger 61 and the one end side 64s of the heat dissipation member 64 in close contact with each other.

The liquid cooling unit 60 in the present embodiment further includes a top surface cooling wall (a first cooling wall) 67 and a bottom surface cooling wall (a second cooling wall) 68.

The top surface cooling wall 67 is disposed along an X-Y plane (a third plane) crossing each of the Y-Z plane and the X-Z plane, and covers one end surface side located at the upper side (+Z) of each of the heat exchanger 61, the tank 63, the heat dissipation member 64, and the fan 70. In FIG. 3, in order to facilitate visualization of the drawings, the top surface cooling wall 67 is illustrated in a state of being separated at the upper side (+Z), but in the liquid cooling unit 60 in the present embodiment, the top surface cooling wall 67 covers the space K in a state of being in close contact with one end side of each member.

The bottom surface cooling wall 68 is disposed along the X-Y plane to cover the other end surface side, which is the lower side (-Z), of each of the heat exchanger 61, the tank 63, the heat dissipation member 64, and the fan 70. In the case of the present embodiment, the bottom surface cooling wall 68 covers the space K in a state of being in close contact with the other end surface side of each member.

As described above, the heat exchanger 61, the tank 63, and the heat dissipation member 64, which are the components of the liquid cooling unit 60, the fan 70, the top surface cooling wall 67, and the bottom surface cooling wall 68 are arranged so as to surround the space K from the respective directions different from each other. That is, in the cooling device 6 of the present embodiment, since the top surface cooling wall 67 and the bottom surface cooling wall 68 surround the up-down direction Z sides of the space K, a sealing degree of the space K is further increased. Therefore, the leakage of the cooling air F from the space K can be suppressed.

In the liquid cooling unit 60 in the present embodiment, the components are disposed so as to open the rear side (-Y), which is one direction side, of the space K. In the cooling device 6 of the present embodiment, the fan 70 is disposed at the rear side (-Y) corresponding to an opening that opens the space K.

The fan 70 is disposed along the X-Z plane so as to face the tank 63 of the liquid cooling unit 60 and to surround the space K. The fan 70 formed of the axial fan is disposed in an orientation in which the rotational axis of the impeller coincides with the Y direction.

That is, in other words, in the cooling device 6 of the present embodiment, the heat exchanger 61, the tank 63, the heat dissipation member 64, and the fan 70 are arranged so as to surround the space K from four directions different from each other.

In the cooling device 6 of the present embodiment, when the fan 70 rotates, the air in the space K is discharged to the outside, and the space K becomes a negative pressure state. As a result, the cooling device 6 generates a flow of the cooling air F from the outside of the heat dissipation member 64 toward the fan 70 through the inner space K. The heat dissipation member 64 is cooled by the cooling air F.

The cooling air F having passed through the heat dissipation member 64 flows along the surface of the tank 63, changes the direction toward the fan 70 by colliding with the back surface 611 of the heat exchanger 61 facing the heat dissipation member 64, and is discharged to the outside of the space K. The cooling air F discharged from the fan 70 is discharged to the outside of the projector 1 via an exhaust port 5a provided to the exterior housing 5 shown in FIG. 1.

As described above, the cooling device 6 of the present embodiment includes the liquid cooling unit 60 including the heat exchanger 61 that absorbs the heat generated by the light source unit 2, which is the heat source, with the liquid refrigerant, the pump 62 that causes the liquid refrigerant to flow, the tank 63 that stores the liquid refrigerant, and the heat dissipation member 64 that dissipates the heat of the liquid refrigerant, and the fan 70 that causes the cooling air F to flow to the heat dissipation member 64 of the liquid cooling unit 60. The cooling air F flows through the space K surrounded by at least some of the components of the liquid cooling unit 60.

According to the cooling device 6 of the present embodiment, since the space K surrounded by the components of the liquid cooling unit 60 from five directions different from each other functions as a duct forming a flow path of the cooling air F passing through the heat dissipation member 64, the device configuration can be reduced in size compared to when a duct is separately disposed. In addition, since none of the components of the liquid cooling unit 60 is disposed at a position that blocks the flow of the cooling air F in the space K, the cooling air F that has passed through the heat dissipation member 64 smoothly flows through the space K and is then discharged. Therefore, the cooling efficiency of the heat dissipation member 64 can be increased.

Therefore, since the cooling device 6 of the present embodiment efficiently cools the heat dissipation member 64 without providing a duct, it is possible to provide a cooling device that efficiently cools the light source unit 2, which is the heat source, while suppressing an increase in size of the device configuration.

According to the projector 1 of the present embodiment, since the cooling device 6 that efficiently cools the light source unit 2 while suppressing an increase in size is provided, it is possible to provide a projector that is small in size and suppresses heat generation of the light source unit 2 as the heat source.

### Second Embodiment

Subsequently, a cooling device according to a second embodiment of the present disclosure will be described. The cooling device of the present embodiment is different from the cooling device 6 of the first embodiment in a layout of the components of the liquid cooling unit. Therefore, hereinafter, differences in the layout of the liquid cooling unit will be mainly described, and the same reference numerals are given to the common configurations to omit the description of the details thereof.

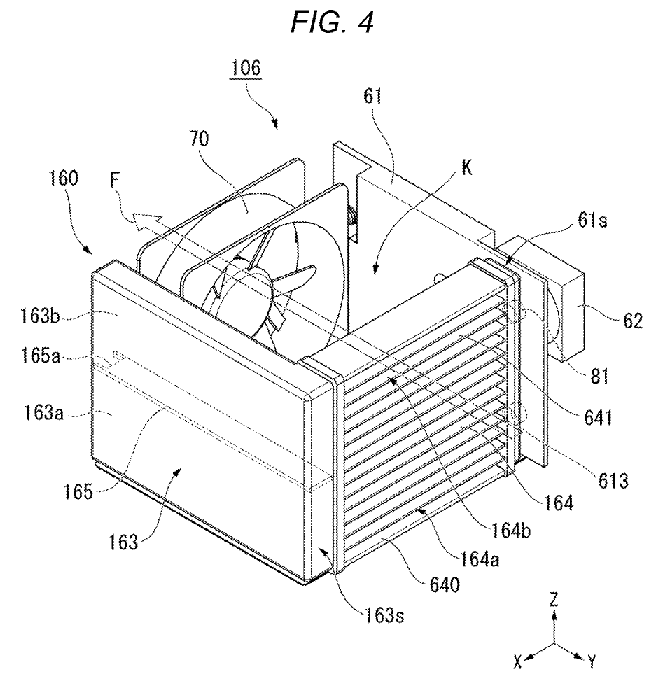

FIG. 4 is a perspective view illustrating a configuration of a cooling device 106 of the present embodiment.

As shown in FIG. 4, the cooling device 106 of the present embodiment includes a liquid cooling unit 160 and the fan 70. The liquid cooling unit 160 includes the heat exchanger 61, the pump 62, a tank 163, and a heat dissipation member 164 as components. In FIG. 4, in order to facilitate visualization of the drawing, the top surface cooling wall 67 is not shown.

In the liquid cooling unit 160 in the present embodiment, the tank 163 is disposed along the Y-Z plane (the first plane) so as to face the heat exchanger 61. The tank 163 in the present embodiment has an equivalent size as the heat exchanger 61 in plan view from the left-right direction X. The tank 163 and the heat exchanger 61 are arranged in an orientation in which the thickness directions coincide with the left-right direction X. Specifically, the tank 163 covers the space K from the left side (-X) in the left-right direction X, and the heat exchanger 61 covers the space K from the right side (+X) in the left-right direction X.

The heat dissipation member 164 is disposed along the X-Z plane (the second plane) crossing the Y-Z plane. The heat dissipation member 164 is disposed in an orientation in which the thickness direction coincides with the front-rear direction Y. The heat dissipation member 164 is coupled to the one end side 61s located at the front side (+Y) of the heat exchanger 61 and one end side 163s located at the front side (+Y) of the tank 163. Thus, the heat dissipation member 164 covers the space K from the front side (+Y) in the front-rear direction Y. In the case of the present embodiment, the heat dissipation member 164 is coupled to the one end side 61s of the heat exchanger 61 and the one end side 163s of the tank 163 in close contact with each other.

The heat dissipation member 164 of the present embodiment causes the liquid refrigerant to flow into or out of the heat exchanger 61 without intervention of the tank 163. The heat dissipation member 164 includes a first heat dissipation portion 164a and a second heat dissipation portion 164b.

The first heat dissipation portion 164a includes a plurality of first heat dissipation members 640 each having a plate shape extending in the left-right direction X and arranged side by side in the up-down direction Z. The first heat dissipation portion 164a causes the liquid refrigerant having inflowed from the inflow portion 612 of the heat exchanger 61 to flow from the -X side toward the +X side through the cooling flow path in each of the first heat dissipation members 640 to thereby exchange heat between cooling air F passing through the first heat dissipation portion 164a and the liquid refrigerant. Thus, the first heat dissipation portion 164a decreases the temperature of the liquid refrigerant flowing through the plurality of first heat dissipation members 640.

In the cooling device 106 of the present embodiment, the liquid refrigerant having been cooled by the first heat dissipation portion 164a flows into the second heat dissipation portion 164b via the tank 163.

The tank 163 includes a first storage portion 163a and a second storage portion 163b. The first storage portion 163a and the second storage portion 163b are arranged side by side in order from the -Z side toward the +Z side in the up-down direction Z. The first storage portion 163a and the second storage portion 163b communicate with each other via a cutout 165a disposed at one end side (-Y side) of a partition member 165. Therefore, the liquid refrigerant can flow from the first storage portion 163a into the second storage portion 163b via the cutout 165a.

The first storage portion 163a is coupled to the first heat dissipation portion 164a of the heat dissipation member 164, and the liquid refrigerant from the first heat dissipation portion 164a flows into the first storage portion 163a. The second storage portion 163b causes the liquid refrigerant having inflowed from the first storage portion 163a to flow into the second heat dissipation portion 164b of the heat dissipation member 164.

Similarly to the first heat dissipation portion 164a, the second heat dissipation portion 164b includes a plurality of second heat dissipation members 641 each having a plate shape extending in the left-right direction X and arranged side by side in the up-down direction Z. The second heat dissipation portion 164b causes the liquid refrigerant having inflowed from the second storage portion 163b of the tank 163 to flow from the +X side toward the -X side in the cooling flow path formed in each of the second heat dissipation members 641 to thereby exchange the heat between the cooling air F passing through the second heat dissipation portion 164b and the liquid refrigerant. As a result, the second heat dissipation portion 164b decreases the temperature of the liquid refrigerant flowing through the plurality of second heat dissipation members 641.

The liquid refrigerant the heat of which has been dissipated by the second heat dissipation portion 164b is discharged to the pump 62 via a piping member 81. The piping member 81 is disposed below the liquid surface of the liquid refrigerant stored in a coupling portion with the piping member 81 in the second heat dissipation portion 164b in the vertical direction (lower side -Z in the up-down direction Z). According to this configuration, since it is difficult for air bubbles to enter the liquid refrigerant sent to the pump 62 via the piping member 81, it is possible to suppress an occurrence of an operation failure due to air entrainment of the pump 62.

The piping member 81 is directly coupled to the pump 62 in a state of penetrating the heat exchanger 61 without communicating with the cooling flow path in the heat exchanger 61. Therefore, the liquid refrigerant flowing in the piping member 81 is supplied to the pump 62 without mixing with the liquid refrigerant flowing in the heat exchanger 61.

As described above, in the liquid cooling unit 160 in the present embodiment, the fan 70 is disposed along the X-Z plane so as to face the heat dissipation member 164 and surround the space K, and the tank 163 is disposed along the Y-Z plane so as to face the heat exchanger 61 and surround the space K.

In the cooling device 106 of the present embodiment, when the fan 70 rotates, the air in the space K is discharged to the outside and the space K becomes a negative pressure state, and the liquid refrigerant flowing through the heat dissipation member 164 can be cooled by the cooling air F flowing from the outside of the heat dissipation member 164 toward the fan 70 through the inner space K.

Also in the cooling device 106 of the present embodiment, the space K surrounded by the components of the liquid cooling unit 160 functions as a duct forming a flow path of the cooling air F from the heat dissipation member 164 to the fan 70. The liquid refrigerant flowing through the liquid cooling unit 160 can be cooled. Therefore, since the cooling device 106 of the present embodiment efficiently cools the heat dissipation member 164 without providing a duct, it is possible to efficiently cool the light source unit 2, which is the heat source, while suppressing an increase in size of the device configuration. In addition, in the case of the present embodiment, since the heat dissipation member 164 and the fan 70 are disposed on a straight line along the front-rear direction Y, it is possible to cause the cooling air F to flow more smoothly while suppressing the driving force of the fan 70. Therefore, the power consumption of the fan 70 can be suppressed.

### Third Embodiment

Subsequently, a cooling device according to a third embodiment of the present disclosure will be described. The present embodiment is different from the embodiment described above in the layout of the components of the liquid cooling unit. Therefore, hereinafter, differences in the layout of the liquid cooling unit will be mainly described, and the same reference numerals are given to the common configurations to omit the description of the details thereof.

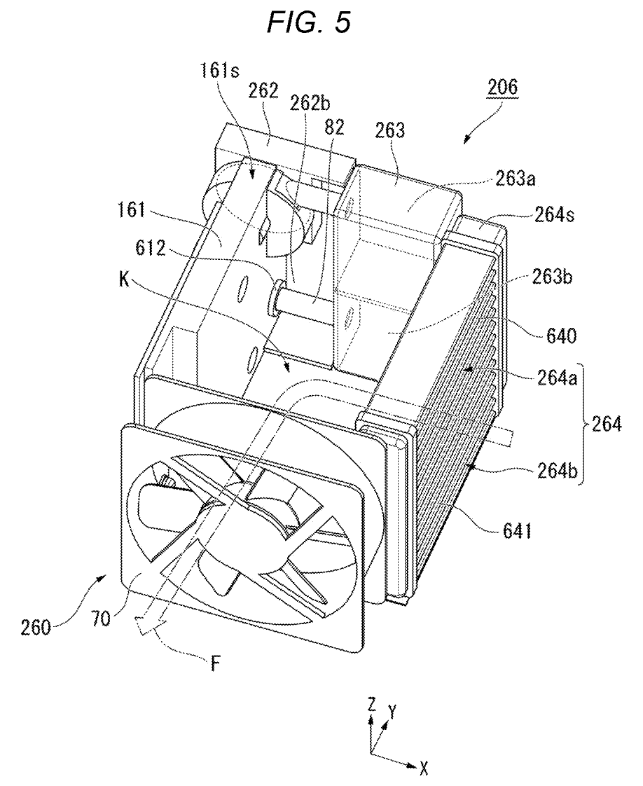

FIG. 5 is a perspective view illustrating a configuration of a cooling device 206 of the present embodiment.

As shown in FIG. 5, the cooling device 206 of the present embodiment includes a liquid cooling unit 260 and the fan 70. The liquid cooling unit 260 includes a heat exchanger 161, a pump 262, a tank 263, and a heat dissipation member 264 as components. In FIG. 5, the top surface cooling wall 67 and the bottom surface cooling wall 68 are not shown in order to facilitate visualization of the drawing.

The heat exchanger 161 and the heat dissipation member 264 are disposed along the Y-Z plane (the first plane) so as to face each other. The tank 263 is disposed along the X-Z plane (the second plane).

The tank 263 is coupled to one end side 161s located at the front side (+Y) of the heat exchanger 161 and one end side 264s located at the front side (+Y) of the heat dissipation member 264.

The tank 263 includes a first storage portion 263a and a second storage portion 263b. The first storage portion 263a and the second storage portion 263b are arranged side by side in order from the +Z side toward the -Z side in the up-down direction Z. The liquid refrigerant discharged from the heat exchanger 161 by the pump 262 flows into the first storage portion 263a of the tank 263. The liquid refrigerant the heat of which has been dissipated by the heat dissipation member 264 flows into the second storage portion 263b of the tank 263, and the second storage portion 263b is coupled to the inflow portion 612 of the heat exchanger 161 via a piping member 82.

The +X side of the tank 263 is coupled to the one end side 264s of the heat dissipation member 264 in close contact with each other. Incidentally, since the -X side of the tank 263 is coupled to the inflow portion 612 of the heat exchanger 161 via the piping member 82, a gap is formed between the -X side of the tank 263 and the heat exchanger 161.

The pump 262 is disposed to surround the space K from the front side (+Y) in the front-rear direction Y together with the tank 263.

The heat dissipation member 264 in the present embodiment includes a first heat dissipation portion 264a and a second heat dissipation portion 264b.

The first heat dissipation portion 264a includes a plurality of first heat dissipation members 640 each having a plate shape extending in the front-rear direction Y and arranged side by side in the up-down direction Z. The first heat dissipation portion 264a causes the liquid refrigerant having inflowed from the first storage portion 263a of the tank 263 to flow from the +Y side toward the -Y side through the cooling flow path in each of the first heat dissipation members 640 to thereby exchange heat between cooling air F passing through the first heat dissipation portion 264a and the liquid refrigerant. Thus, the first heat dissipation portion 264a decreases the temperature of the liquid refrigerant flowing through the plurality of first heat dissipation members 640.

The liquid refrigerant cooled by the first heat dissipation portion 264a flows into the second heat dissipation portion 264b. Similarly to the first heat dissipation portion 264a, the second heat dissipation portion 264b includes a plurality of second heat dissipation members 641 each having a plate shape extending in the front-rear direction Y and arranged side by side in the up-down direction Z. The second heat dissipation portion 264b causes the liquid refrigerant having inflowed from the first heat dissipation portion 264a to flow from the -Y side toward the +Y side in the cooling flow path formed in each of the second heat dissipation members 641 to thereby exchange the heat between the cooling air F passing through the second heat dissipation portion 264b and the liquid refrigerant. Thus, the second heat dissipation portion 264b releases the heat of the liquid refrigerant flowing through each of the second heat dissipation members 641.

The liquid refrigerant the heat of which has been dissipated by the second heat dissipation portion 264b flows into the second storage portion 263b of the tank 263. The second storage portion 263b discharges the liquid refrigerant to the inflow portion 612 of the heat exchanger 161 via the piping member 82. The piping member 82 is disposed below the liquid surface of the liquid refrigerant stored in the second storage portion 263b in the vertical direction (lower side -Z in the up-down direction Z). According to this configuration, since it is difficult for air bubbles to enter the liquid refrigerant sent to the heat exchanger 161 via the piping member 82, it is possible to suppress an occurrence of an operation failure due to air entrainment of the pump 262.

The fan 70 is disposed along the X-Z plane so as to face the pump 262 and the tank 263 of the liquid cooling unit 260 and to surround the space K.

In the cooling device 206 of the present embodiment, the heat exchanger 161, the pump 262, the tank 263, the heat dissipation member 264, and the fan 70 are arranged so as to surround the space K from four directions different from each other, respectively.

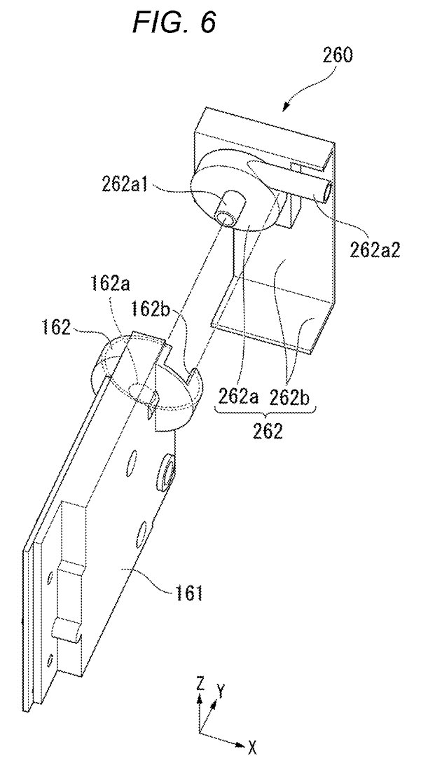

FIG. 6 is an exploded perspective view showing a configuration of a principal part of the liquid cooling unit 260.

As shown in FIG. 6, in the liquid cooling unit 260 of the present embodiment, the pump 262 includes a pump portion 262a and a housing portion 262b. The pump portion 262a is a region that functions as a pump main body that supplies the heat exchanger 161 with the liquid refrigerant flowing therein from the tank 263. The pump portion 262a includes an inflow portion 262a1 that protrudes toward the rear side -Y in the front-rear direction Y and causes the liquid refrigerant to inflow from the heat exchanger 161, and a discharge portion 262a2 that protrudes toward the right side +X in the left-right direction X and discharges the liquid refrigerant to the tank 263.

The heat exchanger 161 in the present embodiment includes a pump coupling portion 162 to be coupled to the pump 262. The pump coupling portion 162 has a cylindrical shape for receiving the pump portion 262a, and includes a discharge portion 162a to be coupled to the inflow portion 262a1 of the pump portion 262a, and a housing groove 162b for housing the discharge portion 262a2 of the pump portion 262a.

The housing portion 262b holds the pump portion 262a. As illustrated in FIG. 5, the housing portion 262b is disposed along the X-Z plane so as to cover a gap generated between the tank 263 and the heat exchanger 161. Accordingly, the housing portion 262b of the pump 262 covers the gap between the tank 263 and the heat exchanger 161 from the front side (+Y) in the front-rear direction Y.

In the cooling device 206 of the present embodiment, when the fan 70 rotates, the air in the space K is discharged to the outside, and the space K becomes a negative pressure state. As a result, the cooling device 206 generates a flow of the cooling air F from the outside of the heat dissipation member 264 toward the fan 70 through the inner space K.

The cooling air F having passed through the heat dissipation member 264 flows along the surfaces of the tank 263 and the pump 262, changes the direction toward the fan 70 by colliding with the back surface 611 of the heat exchanger 161 facing the heat dissipation member 264, and is discharged to the outside of the space K.

In the liquid cooling unit 260 in the present embodiment, since the housing portion 262b covers the gap generated between the tank 263 and the heat exchanger 161 at the front side (+Y) of the space K, leakage of the cooling air F flowing through the space K from the gap between the tank 263 and the heat exchanger 161 is suppressed. Therefore, the flow of the cooling air F that passes through the heat dissipation member 264 and is discharged to the outside of the space K can be smoothly generated.

As described above, according to the cooling device 206 of the present embodiment, similarly to the embodiments described above, since the heat dissipation member 264 is efficiently cooled without providing a duct, it is possible to efficiently cool the light source unit 2 which is the heat source while suppressing an increase in size of the device configuration.

The technical scope of the present disclosure is not limited to the embodiment described above, and various changes can be made thereto to the extent that the changes do not depart from the intent of the present disclosure.

In the embodiment described above, the fan 70 is exemplified by the exhaust fan disposed so as to surround the space K together with the components of the liquid cooling unit 60, 160, or 260, but the cooling device of the present disclosure may adopt a configuration in which an intake fan that directly sends the sucked air into the space K as the cooling air F is used as the fan. When the fan constituting the intake fan is used as described above, the intake fan may be disposed in an anterior stage of the heat dissipation member 64, 164. The cooling air F sucked into the space K is directly discharged from the exhaust port 5a of the exterior housing 5.

### Summary of Present Disclosure

The present disclosure will be summarized below as appendices.

### Appendix 1

A cooling device including:
a liquid cooling unit including a heat exchanger configured to absorb heat generated by a heat source with a liquid refrigerant, a pump configured to cause the liquid refrigerant to flow, a tank configured to store the liquid refrigerant, and a heat dissipation member configured to dissipate heat of the liquid refrigerant; and
a fan configured to cause cooling air to flow to the heat dissipation member of the liquid cooling unit, wherein
the cooling air flows through a space surrounded by at least some of components of the liquid cooling unit.

According to the cooling device having this configuration, since the space surrounded by at least some of the components of the liquid cooling unit functions as a duct forming a flow path of the cooling air passing through the heat dissipation member, the device configuration can be reduced in size compared to when the duct is separately disposed. In addition, since none of the components of the liquid cooling unit is disposed at a position that blocks the flow of the cooling air in the space, the cooling air that has passed through the heat dissipation member smoothly flows through the space and is then discharged. Therefore, the cooling efficiency of the heat dissipation member can be increased.

Therefore, since the cooling device having this configuration efficiently cools the heat dissipation member without providing a duct, it is possible to provide a cooling device that efficiently cools the heat source while suppressing an increase in size of the device configuration.

### Appendix 2

The cooling device according to Appendix 1, wherein
the heat exchanger, the tank, the heat dissipation member, and the fan are arranged so as to surround the space from respective directions different from each other.

According to this configuration, it is possible to form a space that is surrounded by the heat exchanger, the tank, the heat dissipation member, and the fan from four different directions and functions as a flow path of the cooling air.

### Appendix 3

The cooling device according to Appendix 2, wherein
the heat exchanger is disposed along a first plane,
the heat dissipation member is disposed along the first plane so as to face the heat exchanger,
the tank is disposed along a second plane crossing the first plane and is coupled to one end side of the heat exchanger and one end side of the heat dissipation member, and
the fan is disposed along the second plane so as to face the tank and to surround the space.

According to this configuration, the cooling air that has passed through the heat dissipation member flows along the surface of the tank, changes the direction toward the fan by colliding with the heat exchanger facing the heat dissipation member, and is discharged to the outside of the space. Therefore, the flow path of the cooling air can be favorably configured.

### Appendix 4

The cooling device according to Appendix 2, wherein
the heat exchanger is disposed along a first plane,
the tank is disposed along the first plane so as to face the heat exchanger,
the heat dissipation member is disposed along a second plane crossing the first plane and is coupled to one end side of the heat exchanger and one end side of the tank, and
the fan is disposed along the second plane so as to face the heat dissipation member and to surround the space.

According to this configuration, since the heat dissipation member and the fan are arranged side by side on a straight line, it is possible to cause the cooling air to flow more smoothly while suppressing the driving force of the fan. Therefore, the power consumption of the fan can be suppressed.

### Appendix 5

The cooling device according to Appendix 1, wherein
the heat exchanger, the pump, the tank, the heat dissipation member, and the fan are arranged so as to surround the space from respective directions different from each other.

According to this configuration, it is possible to form a space that is surrounded by the pump, the tank, the heat dissipation member, and the fan from four different directions and functions as a flow path of the cooling air.

### Appendix 6

The cooling device according to Appendix 5, wherein
the pump includes a pump portion and a housing portion configured to hold the pump portion,
the heat exchanger is disposed along a first plane,
the heat dissipation member is disposed along the first plane so as to face the heat exchanger,
the tank is disposed along a second plane crossing the first plane and is coupled to one end side of the heat dissipation member and one end side of the heat exchanger,
the housing portion of the pump is disposed along the second plane so as to cover a gap generated between the tank and the heat exchanger, and
the fan is disposed along the second plane so as to face the tank and the pump and to surround the space.

According to this configuration, since the housing portion covers the gap generated between the tank and the heat exchanger, leakage of the cooling air flowing through the space from the gap between the tank and the heat exchanger is suppressed. Therefore, the flow of the cooling air that passes through the heat dissipation member and is discharged to the outside of the space can be smoothly generated.

### Appendix 7

The cooling device according to any one of Appendices 3, 4, and 6, wherein
the liquid cooling unit further includes:
   a first cooling wall disposed along a third plane crossing the first plane and the second plane and configured to cover one end surface side of each of the heat exchanger, the tank, the heat dissipation member, and the fan; and
   a second cooling wall disposed along the third plane and configured to cover another end surface side of each of the heat exchanger, the tank, the heat dissipation member, and the fan.

According to this configuration, since the liquid cooling unit further including the first cooling wall and the second cooling wall is provided, the number of directions in which the components of the liquid cooling unit surround the space can be increased. Therefore, since the sealing degree of the space is increased, the leakage of the cooling air from the space is suppressed, and the flow of the cooling air can be made smooth.

### Appendix 8

A projector including:
a cooling device according to any one of Appendices 1 to 7; and
the heat source.

According to the projector having this configuration, since the cooling device that efficiently cools the light source unit while suppressing an increase in size is provided, it is possible to provide the projector that suppresses heat generation of the heat source while being small in size.

### Appendix 9

The projector according to Appendix 8, further including:
a light source unit;
an image forming unit configured to modulate light emitted from the light source unit in accordance with image information to generate image light; and
a projection optical unit configured to project the image light generated by the image forming unit, wherein
the heat source is the light source unit.

According to this configuration, it is possible to provide a projector that is small in size and suppresses heat generation of the light source unit as the heat source.

What is claimed is:

1. A cooling device comprising:
a liquid cooling unit including a heat exchanger configured to absorb heat generated by a heat source with a liquid refrigerant, a pump configured to cause the liquid refrigerant to flow, a tank configured to store the liquid refrigerant, and a heat dissipation member configured to dissipate heat of the liquid refrigerant; and
a fan configured to cause cooling air to flow to the heat dissipation member of the liquid cooling unit, wherein
the cooling air flows through a space surrounded by at least some of components of the liquid cooling unit.

2. The cooling device according to claim 1, wherein
the heat exchanger, the tank, the heat dissipation member, and the fan are arranged so as to surround the space from respective directions different from each other.

3. The cooling device according to claim 2, wherein
the heat exchanger is disposed along a first plane,
the heat dissipation member is disposed along the first plane so as to face the heat exchanger,
the tank is disposed along a second plane crossing the first plane and is coupled to one end side of the heat exchanger and one end side of the heat dissipation member, and
the fan is disposed along the second plane so as to face the tank and to surround the space.

4. The cooling device according to claim 2, wherein
the heat exchanger is disposed along a first plane,
the tank is disposed along the first plane so as to face the heat exchanger,
the heat dissipation member is disposed along a second plane crossing the first plane and is coupled to one end side of the heat exchanger and one end side of the tank, and
the fan is disposed along the second plane so as to face the heat dissipation member and to surround the space.

5. The cooling device according to claim 1, wherein
the heat exchanger, the pump, the tank, the heat dissipation member, and the fan are arranged so as to surround the space from respective directions different from each other.

6. The cooling device according to claim 5, wherein
the pump includes a pump portion and a housing portion configured to hold the pump portion,
the heat exchanger is disposed along a first plane,
the heat dissipation member is disposed along the first plane so as to face the heat exchanger,
the tank is disposed along a second plane crossing the first plane and is coupled to one end side of the heat dissipation member and one end side of the heat exchanger,
the housing portion of the pump is disposed along the second plane so as to cover a gap generated between the tank and the heat exchanger, and
the fan is disposed along the second plane so as to face the tank and the pump and to surround the space.

7. The cooling device according to claim 3, wherein
the liquid cooling unit further includes:
a first cooling wall disposed along a third plane crossing the first plane and the second plane and configured to cover one end surface side of each of the heat exchanger, the tank, the heat dissipation member, and the fan; and
a second cooling wall disposed along the third plane and configured to cover another end surface side of each of the heat exchanger, the tank, the heat dissipation member, and the fan.

8. A projector comprising:
a cooling device according to claim 1; and
the heat source.

9. The projector according to claim 8, further comprising:
a light source unit;
an image forming unit configured to modulate light emitted from the light source unit in accordance with image information to generate image light; and
a projection optical unit configured to project the image light generated by the image forming unit, wherein
the heat source is the light source unit.
